(19) United States
(12) Patent Application Publication
(10) Pub. No.: US 2026/0262532 A1
(43) Pub. Date: Sep. 3, 2026

(54) SEMICONDUCTOR DEVICE AND METHOD OF MANUFACTURING SEMICONDUCTOR DEVICE

(71) Applicant: Mitsubishi Electric Corporation, Tokyo (JP)

(72) Inventors: Kazuki IIDA, Tokyo (JP); Yuki YANO, Tokyo (JP)

(73) Assignee: Mitsubishi Electric Corporation, Tokyo (JP)

(21) Appl. No.: 19/159,568

(22) PCT Filed: Mar. 10, 2023
(86) PCT No.: PCT/JP2023/009365

§ 371 Date: Aug. 25, 2025

(51) Int. Cl. H10W 74/01; H10W 74/10

(52) U.S. Cl. CPC H10W 74/016; H10W 74/111

(57) ABSTRACT

It is an object to provide a method of manufacturing a semiconductor device improving productivity by improving releasability of a sealing material from a mold. A method of manufacturing a semiconductor device includes: filling, with a sealing material, an interior of a mold in which an object-to-be-sealed including a semiconductor element is installed and which is opened, the interior of the mold being filled while at least one protrusion projects into the interior of the mold; sealing the object-to-be-sealed by curing the sealing material; and releasing the cured sealing material from the mold. Releasing the sealing material includes: pulling down the projecting protrusion once; and after pulling down the protrusion once, pushing up the cured sealing material with the protrusion.

### TECHNICAL FIELD

The present disclosure relates to a semiconductor device and a method of manufacturing the semiconductor device.

### BACKGROUND ART

As a method of molding a package for a semiconductor device, a resin sealing method of molding a resin in a mold and sealing a semiconductor element in an interior of the resin is known as shown in Patent Document 1. In the resin sealing method, a mold release agent is applied in advance to an interior of the mold to ensure releasability of the resin from the mold.

### PRIOR ART DOCUMENTS

### Patent Document

Patent Document 1: Japanese Patent Application Laid-Open No. 2015-207705

### SUMMARY

### Problem to be Solved by the Invention

When the mold release agent applied to the mold is separated by multiple use of the mold, releasability of the resin from the mold is reduced. When the resin sealing step is performed in this state, a portion of the resin sticks to the mold. When the resin after being molded is removed from the mold, a portion of the resin is separated, and an object-to-be-sealed, such as a semiconductor element, is exposed from the separated portion. As described above, reduction in releasability causes a manufacturing failure of the semiconductor device. Periodic cleaning of the mold and re-application of the mold release agent are thus required. A melamine resin, a releasability recovery resin, and the like are used for cleaning of the mold, and one cleaning takes a significant amount of time.

The present disclosure has been conceived to solve the above-mentioned problem, and it is an object of the present disclosure to provide a method of manufacturing a semiconductor device improving productivity by improving releasability of a sealing material from a mold.

### Means to Solve the Problem

A method of manufacturing a semiconductor device according to the present disclosure includes: filling, with a sealing material, an interior of a mold in which an object-to-be-sealed including a semiconductor element is installed and which is opened, the interior of the mold being filled while at least one protrusion projects into the interior of the mold; sealing the object-to-be-sealed by curing the sealing material; and releasing the cured sealing material from the mold. Releasing the sealing material includes: pulling down the projecting protrusion once; and after pulling down the protrusion once, pushing up the cured sealing material with the protrusion.

Effects of the Invention

According to the method of manufacturing the semiconductor device according to the present disclosure, productivity is improved by improving releasability of the sealing material from the mold.

These and other objects, features, aspects and advantages of the present disclosure will become more apparent from the following detailed description when taken in conjunction with the accompanying drawings.

### BRIEF DESCRIPTION OF DRAWINGS

FIG. 1 is a cross-sectional view illustrating a configuration of a semiconductor device according to Embodiment 1.

FIG. 2 is a flowchart showing a method of manufacturing the semiconductor device according to embodiment 1.

FIG. 3 is a diagram illustrating a resin sealing step of the method of manufacturing the semiconductor device.

FIG. 4 is a diagram illustrating the resin sealing step of the method of manufacturing the semiconductor device.

FIG. 5 is a diagram illustrating the resin sealing step of the method of manufacturing the semiconductor device.

FIG. 6 is a diagram illustrating the resin sealing step of the method of manufacturing the semiconductor device.

FIG. 7 is a diagram illustrating the resin sealing step of the method of manufacturing the semiconductor device.

FIG. 8 is a diagram illustrating the resin sealing step of the method of manufacturing the semiconductor device.

FIG. 9 is a plan view illustrating a configuration of a bottom mold for use in a method of manufacturing a semiconductor device according to Embodiment 2.

FIG. 10 is a diagram illustrating a resin sealing step of a method of manufacturing a semiconductor device according to Embodiment 3.

FIG. 11 is a cross-sectional view illustrating a configuration of a semiconductor device according to Embodiment 4.

FIG. 12 is a plan view illustrating a configuration of a back surface of a semiconductor device according to Embodiment 5.

FIG. 13 is a cross-sectional view illustrating a configuration of a semiconductor device according to Embodiment 6.

### DESCRIPTION OF EMBODIMENTS

### Embodiment 1

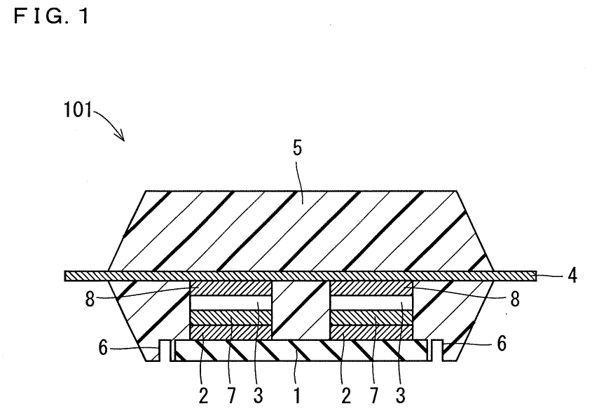

FIG. 1 is a cross-sectional view illustrating a configuration of a semiconductor device 101 according to Embodiment 1. The semiconductor device 101 includes an insulating sheet 1, metal plates 2, semiconductor elements 3, a lead 4, a sealing material 5, and at least one hole 6. The configuration of the semiconductor device 101 illustrated in FIG. 1 and subsequent drawings has been simplified, and wiring, signal terminals, and the like electrically connected to the semiconductor elements 3 are not illustrated.

The insulating sheet 1 is formed of a material having electrical insulation and high thermal conductivity. The insulating sheet 1 is an epoxy resin, for example. The insulating sheet 1 may include a filler formed of silicon oxide (SiO₂), aluminum oxide (Al₂O₃), boron nitride (BN), and the like. A back surface of the insulating sheet 1 forms a portion of an outer surface of the semiconductor device 101. Metal foil (not illustrated) may be formed over the back surface of the insulating sheet 1. Heat dissipation fins can be attached to the metal foil after completion of the semiconductor device 101. The metal foil forms thermal connection between the semiconductor elements 3 in an interior of the semiconductor device 101 and the heat dissipation fins external to the semiconductor device 101.

The metal plates 2 are arranged over a front surface of the insulating sheet 1. The metal plates 2 are formed of a material having good thermal conductivity, such as an aluminum alloy and copper.

The semiconductor elements 3 are bonded to the metal plates 2 via bonding materials 7. That is to say, the semiconductor elements 3 are mounted to the front surface of the insulating sheet 1 via the bonding materials 7 and the metal plates 2. The bonding materials 7 have electrical conductivity. The bonding materials 7 are soft solder, such as solder. The semiconductor elements 3 are formed of a semiconductor, such as Si. Alternatively, the semiconductor elements 3 are formed of a so-called wide bandgap semiconductor, such as SiC, GaN, Ga₂O₃, and diamond, having a wider bandgap than Si. The semiconductor elements 3 are power semiconductor elements, control integrated circuits (ICs) to control the power semiconductor elements, and the like. The semiconductor elements 3 include insulated gate bipolar transistors (IGBTs), metal oxide semiconductor field effect transistors (MOSFETs), Schottky barrier diodes, and the like, for example. The semiconductor elements 3 may include reverse-conducting IGBTs (RC-IGBTs) each including an IGBT and a freewheeling diode formed in a single semiconductor substrate. Two semiconductor elements 3 are mounted to the semiconductor device 101 according to Embodiment 1. The number of semiconductor elements 3 mounted to the semiconductor device 101 is not limited to two, and a required number of semiconductor elements 3 are mounted according to an application of the semiconductor device 101.

The lead 4 is formed of a metal material having a low electrical resistance. The lead 4 is a metal frame obtained by processing a plate of metal, such as copper, to a predetermined shape. The lead 4 forms an internal circuit of the semiconductor device 101 and is configured to be electrically connectable to a circuit (not illustrated) provided externally to the semiconductor device 101. In Embodiment 1, the lead 4 extends to an exterior of the sealing material 5. In other words, end portions of the lead 4 project from the sealing material 5 and form external electrodes connectable to external circuits. Alternatively, external electrodes projecting from the sealing material 5 may be provided as parts different from the lead 4 although not illustrated. In this case, the lead 4 is electrically connected to the external electrodes via metal wires and the like.

Portions of the lead 4 are bonded to upper surfaces of the semiconductor elements 3 via bonding materials 8. The bonding materials 8 have electrical conductivity. The bonding materials 8 are soft solder, such as solder. Members connecting the lead 4 and the semiconductor elements 3 are not limited to the bonding materials 8. Although not illustrated, the lead 4 may electrically be connected to the semiconductor elements 3 via metal wires. The metal wires are formed of aluminum (Al), gold (Au), copper (Cu), and the like. Although not illustrated, portions of the lead 4 may be bonded to the metal plates 2 via the bonding materials 8.

The sealing material 5 seals an object-to-be-sealed including the front surface of the insulating sheet 1, the metal plates 2, the semiconductor elements 3, a portion of the lead 4, and the like. The sealing material 5 is formed of an insulating and curable resin. The sealing material 5 is formed of an epoxy resin, for example. The sealing material 5 may include a filler having good insulation, such as aluminum oxide (Al₂O₃) and silicon (Si). The sealing material 5 is not limited to these materials and is only required to have desired physical properties in terms of a modulus of elasticity, heat resistance, adhesion, a coefficient of linear expansion, and the like.

Holes 6 are formed in one surface (a lower surface in FIG. 1) of the sealing material 5. The lower surface of the sealing material 5 is flush with a surface (the back surface in FIG. 1) of the insulating sheet 1 exposed from the sealing material 5. The holes 6 each have a cylindrical shape. In Embodiment 1, two holes 6 are provided in the sealing material 5. The number of holes 6 is not limited to two and may be one or three or more.

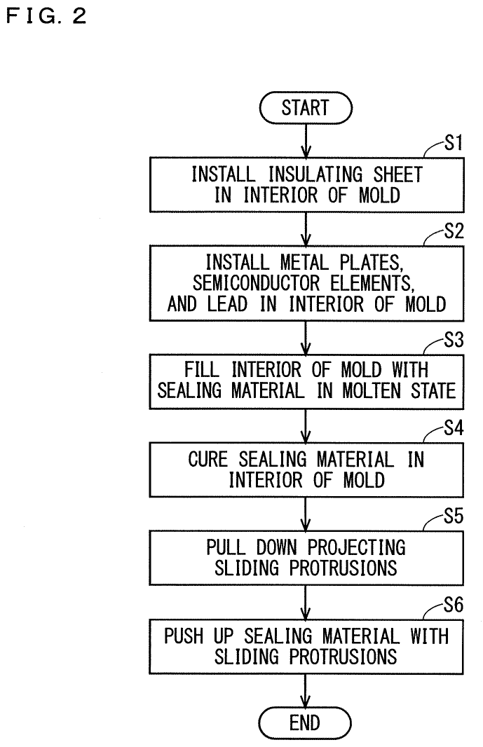

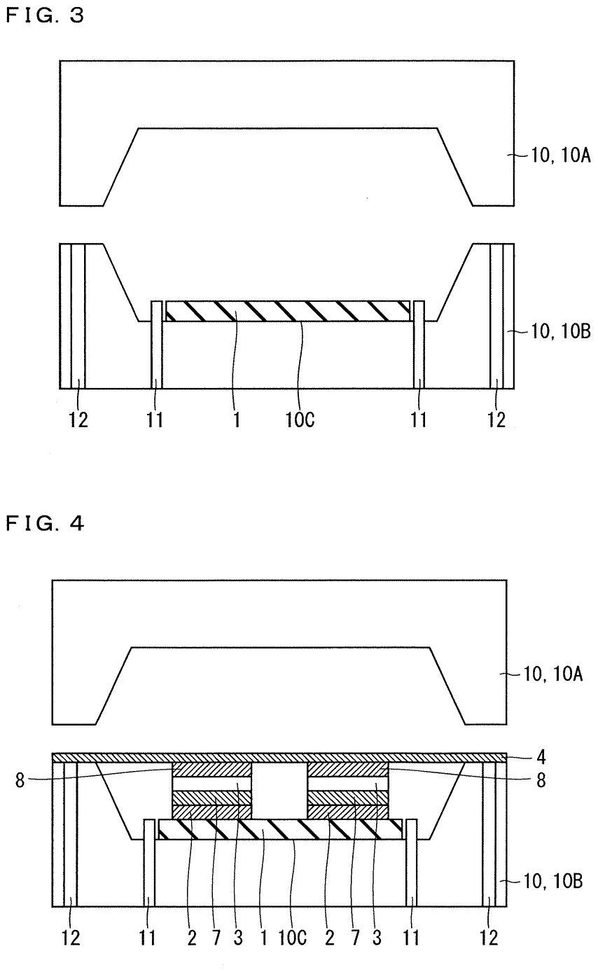

FIG. 2 is a flowchart showing a method of manufacturing the semiconductor device 101 according to Embodiment 1. FIGS. 3 to 8 are diagrams illustrating a resin sealing step of the method of manufacturing the semiconductor device 101. FIGS. 3 to 8 are each a schematic view of a cross section of the semiconductor device 101 and a mold 10 in the resin sealing step.

In this resin sealing step, the mold 10 illustrated in FIG. 3 is used. The mold 10 includes a top mold 10A and a bottom mold 10B. An interior of the mold 10 hereinafter corresponds to a cavity formed by the top mold 10A and the bottom mold 10B. Sliding protrusions 11 leading to the cavity of the mold 10, that is, the interior of the mold 10 are provided in the bottom mold 10B. The sliding protrusions 11 each have a cylindrical shape. In Embodiment 1, two sliding protrusions 11 are provided in the mold 10. The number of sliding protrusions 11 is not limited to two and may be one or three or more. Sliding pins 12 are also provided in the mold 10.

In step S1, the insulating sheet 1 is installed over a portion of an installation surface 10C in the interior of the mold 10. FIG. 3 illustrates a step of installing the insulating sheet 1 in the interior of the mold 10 of the resin sealing step. The installation surface 10C over which the insulating sheet 1 is installed corresponds to a lower surface of the cavity of the mold 10, that is, the interior of the mold 10. In other words, the installation surface 10C corresponds to an upper surface of the bottom mold 10B. A mold release agent may be applied to the installation surface 10C of the mold 10. The insulating sheet 1 is installed in a semi-cured state. In this step S1, the insulating sheet 1 is installed in the interior of the mold 10 with distal ends of the sliding protrusions 11 projecting above the upper surface of the bottom mold 10B, that is, the lower surface of the interior of the mold 10, for example. The insulating sheet 1 may alternatively be installed in the interior of the mold 10 with the distal ends of the sliding protrusions 11 being located at the same elevation as or at a lower elevation than the upper surface of the bottom mold 10B. The metal foil (not illustrated) may be formed in advance over the back surface of the insulating sheet 1 before being installed.

In step S2, the metal plates 2, the semiconductor elements 3, and the lead 4 are installed in the interior of the mold 10. FIG. 4 illustrates a step of installing the metal plates 2, the semiconductor elements 3, and the lead 4 in the interior of the mold 10 of the resin sealing step. The metal plates 2, the semiconductor elements 3, and the lead 4 prepared in this step S2 are integrated in advance by the bonding materials 7 and 8. In other words, the metal plates 2, the semiconductor elements 3, and the lead 4 are prepared as a single part having been bonded together by the bonding materials 7 and 8. The integrated part is manufactured in another bonding step performed in advance. In the bonding step, the metal plates 2, the semiconductor elements 3, and the lead 4 are heated to a temperature above a melting point of the bonding materials 7 and 8 to complete bonding. In step S2, the metal plates 2, the semiconductor elements 3, and the lead 4 as integrated are installed over the front surface of the insulating sheet 1.

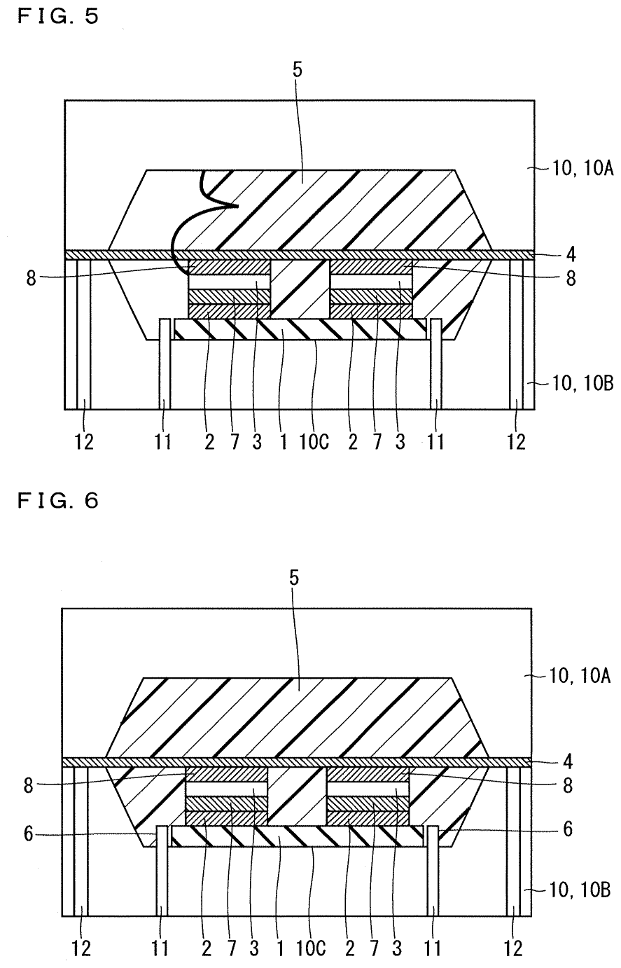

In step S3, the interior of the mold 10 is filled with the sealing material 5 in a molten state. FIG. 5 illustrates a step of filling the interior of the mold 10 with the sealing material 5 in the molten state of the resin sealing step. First, the top mold 10A and the bottom mold 10B are closed. With pressure in the interior of the mold 10 being reduced, the sealing material 5 in the molten state is injected. In this case, the sealing material 5 is injected into the interior of the mold 10 with the sliding protrusions 11 projecting into the interior of the mold 10. The sliding protrusions 11 project into the interior of the mold 10 from regions of the installation surface 10C in the interior of the mold 10 in which the insulating sheet 1 is not installed. The sliding protrusions 11 project above the installation surface 10C of the bottom mold 10B by approximately 1 mm, for example. The sliding protrusions 11 are covered with the sealing material 5 when filling with the sealing material 5 is completed.

In step S4, the interior of the mold 10 is increased in temperature while being pressurized to cure the sealing material 5. FIG. 6 illustrates a step of curing the sealing material 5 in the interior of the mold 10 of the resin sealing step. The interior of the mold 10 is pressurized to tightly fill the interior of the mold 10 with the sealing material 5 in the molten state. A temperature of the sealing material 5 is increased to a curing temperature thereof to cure the sealing material 5. The object-to-be-sealed including the front surface of the insulating sheet 1, the metal plates 2, the semiconductor elements 3, the portion of the lead 4, and the like is sealed in this step S4. On the other hand, the back surface of the insulating sheet 1 is in contact with the installation surface 10C of the mold 10 and is not covered with the sealing material 5. Even after curing of the sealing material 5, the back surface of the insulating sheet 1 is exposed from the lower surface of the sealing material 5. The back surface of the insulating sheet 1 is flush with the lower surface of the sealing material 5. Furthermore, the holes 6 corresponding to the sliding protrusions 11 covered with the sealing material 5 are formed in the sealing material 5 in this step S4. In Embodiment 1, the holes 6 are formed in the lower surface of the sealing material 5. Shapes of the holes 6 match shapes of the sliding protrusions 11.

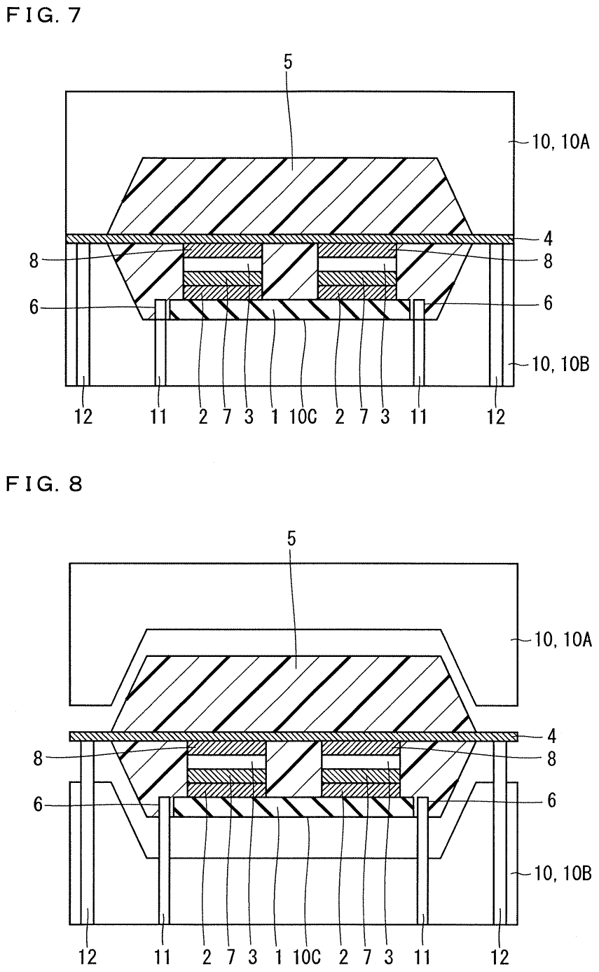

In step S5, the projecting sliding protrusions 11 are pulled down once. FIG. 7 illustrates a step of pulling down the sliding protrusions 11 of the resin sealing step. The distal ends of the sliding protrusions 11 are herein pulled down to the lower surface of the bottom mold 10B, that is, the installation surface 10C. The holes 6 illustrated as cavities in FIG. 7 thus appear. After curing of the sealing material 5, the sliding protrusions 11 are pulled down once to form the cavities to thereby form points of origin of separation between the mold 10 and the sealing material 5.

In step S6, the sealing material 5 is pushed up with the sliding protrusions 11. FIG. 8 illustrates a step of pushing up the sealing material 5 with the sliding protrusions 11 of the resin sealing step. In this case, the top mold 10A and the bottom mold 10B are opened, the lead 4 is lifted by the sliding pins 12, and further the sealing material 5 is lifted by the sliding protrusions 11. This leads to separation of the lead 4 from the mold 10 and release of the sealing material 5 from the mold 10. That is to say, the semiconductor device 101 is released from the mold 10.

As described above, the points of origin of separation are formed by operation to pull down the sliding protrusions 11 once in step S5, and the semiconductor device 101 is easily released from the mold 10 by pushing-up operation with the sliding protrusions 11 in step S6.

After steps S1 to S6 described above, formation of required terminals and the like are performed. Visual inspection, electrical characteristic testing, and the like are conducted to complete the semiconductor device 101.

In summary, the method of manufacturing the semiconductor device 101 according to Embodiment 1 includes: filling, with the sealing material 5, the interior of the mold 10 in which the object-to-be-sealed including the semiconductor elements 3 is installed and which is opened, the interior of the mold 10 being filled while the at least one sliding protrusion 11 projects into the interior of the mold 10; sealing the object-to-be-sealed including the semiconductor elements 3 by curing the sealing material 5; and releasing the cured sealing material 5 from the mold 10. Releasing the sealing material 5 includes: pulling down the projecting sliding protrusion 11 once; and after pulling down the sliding protrusion 11 once, pushing up the cured sealing material 5 with the sliding protrusion 11.

According to the method of manufacturing the semiconductor device 101 as described above, the points of origin of separation between the mold 10 and the sealing material 5 are formed. The sealing material 5 is pushed up with the sliding protrusions 11 with the points of origin of separation being formed, so that the semiconductor device 101 is likely to be separated from the mold 10. In other words, releasability of the resin as the sealing material 5 from the mold 10 is improved. A frequency of cleaning of the mold 10 and a frequency of re-application of the mold release agent are thus suppressed. Furthermore, the number of times the resin sealing step can be performed per cleaning or per application of the mold release agent increases. Reduction in frequency of cleaning of the mold 10 and frequency of re-application of the mold release agent improves productivity of the semiconductor device 101.

Operation to pull down the sliding protrusions 11 and pushing-up operation with the sliding protrusions 11 in Embodiment 1 are each relative operation relative to the sealing material 5. For example, operation to pull down the sliding protrusions 11 may be performed by driving the sliding protrusions 11 downward or may be performed by driving the mold 10 upward. Similarly, pushing-up operation with the sliding protrusions 11 may be performed by driving the sliding protrusions 11 upward or may be performed by driving the mold 10 downward.

### Embodiment 2

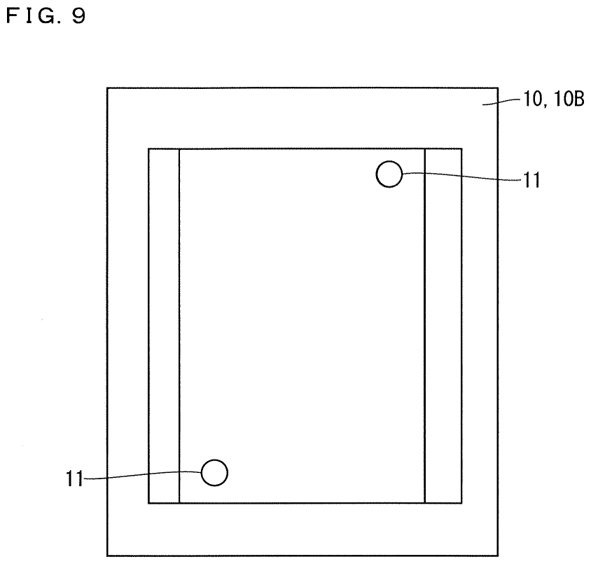

FIG. 9 is a plan view illustrating a configuration of the bottom mold 10B for use in a method of manufacturing a semiconductor device according to Embodiment 2.

The number of sliding protrusions 11 provided in the mold 10 is no more than two. In other words, the sliding protrusions 11 are provided at no more than two locations. When the mold 10 has a plurality of cavities, and a plurality of semiconductor devices are manufactured in the resin sealing step performed once, the number of sliding protrusions 11 is no more than two for each of the cavities.

The method of manufacturing the semiconductor device according to Embodiment 2is the same as the manufacturing method shown in Embodiment 1. The number of holes 6 formed in the sealing material 5 matches the number of sliding protrusions 11. The number of holes 6 of the semiconductor device according to Embodiment 2 is thus no more than two.

Also according to this manufacturing method according to Embodiment 2, the points of origin of separation between the mold 10 and the sealing material 5 are formed in step S5. The sealing material 5 is thus easily released from the mold 10 even when the number of sliding protrusions 11 is no more than two. In particular, in FIG. 9, two sliding protrusions 11 are provided on diagonal corners of an internal space of the mold 10 to facilitate release. Since the number of sliding protrusions 11 is no more than two, the mold 10 is easily designed.

### Embodiment 3

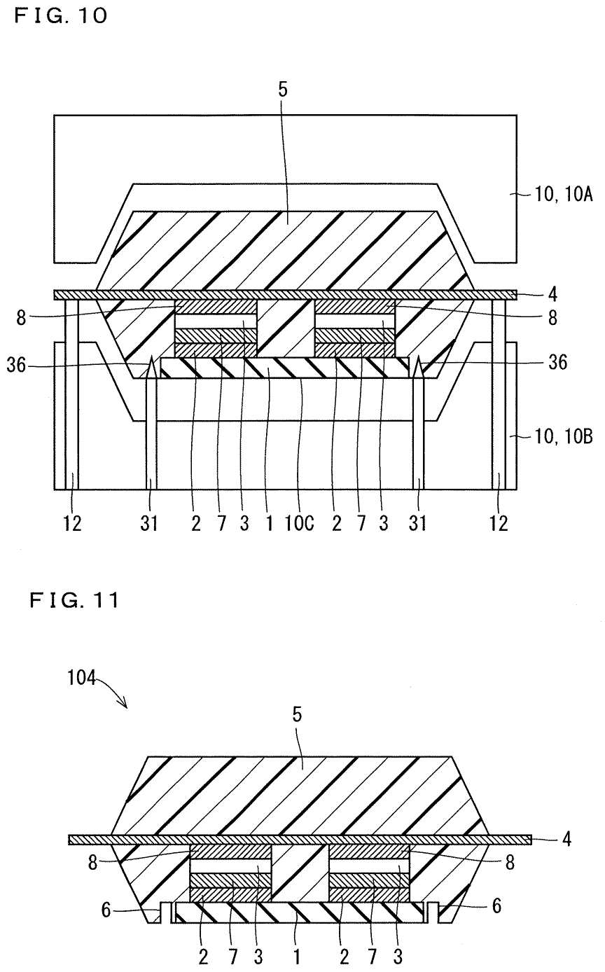

FIG. 10 is a diagram illustrating a resin sealing step of a method of manufacturing a semiconductor device according to Embodiment 3. FIG. 10 illustrates a step of pushing up the sealing material 5 with sliding protrusions 31 of the resin sealing step.

The sliding protrusions 31 each have a shape gradually decreasing in diameter toward a distal end of the sliding protrusion 31. In other words, the sliding protrusions 31 each have a tapered shape. The number of sliding protrusions 31 may be no more than two as in Embodiment 2.

Holes 36 formed in the lower surface of the sealing material 5 each have a shape gradually decreasing in diameter toward a bottom of the hole 36. In other words, the holes 36 each have a tapered shape. This is because shapes of the sliding protrusions 31 are reflected by shapes of the holes 36.

The method of manufacturing the semiconductor device according to Embodiment 3 is the same as the manufacturing method shown in Embodiment 1.

Frictional force between side surfaces of the sliding protrusions 31 each having the tapered shape and the sealing material 5 is smaller than frictional force between side surfaces of the sliding protrusions 31 each having the cylindrical shape and the sealing material 5. The sliding protrusions 31 can thus be pulled down with less driving force in the step of pulling down the sliding protrusions 31 once from the sealing material 5 in step S5. As a result, trouble such as sticking of the sliding protrusions 31 to the holes 36 in the sealing material 5 to fail to pull down the sliding protrusions 31 from the sealing material 5 is prevented. According to the method of manufacturing the semiconductor device according to Embodiment 3, productivity is improved compared with the manufacturing methods according to Embodiments 1 and 2.

### Embodiment 4

FIG. 11 is a cross-sectional view illustrating a configuration of a semiconductor device 104 according to Embodiment 4.

The semiconductor device 104 according to Embodiment 4 is manufactured by the manufacturing method shown in Embodiment 1.

The holes 6 provided in the lower surface of the sealing material 5 each have a cylindrical shape. The number of holes 6 is one or more. The holes 6 are formed in the steps shown in steps S3 and S4. The holes 6 are each formed to have an opening in one surface of the sealing material 5 flush with a surface of the insulating sheet 1 exposed from the sealing material 5 and to have a bottom in the sealing material 5. In step S6, the sliding protrusions 11 enter the holes 6 and push up the sealing material 5. Releasability of the sealing material 5 from the mold 10 is improved. The frequency of cleaning of the mold 10 and the frequency of re-application of the mold release agent are suppressed. As a result, productivity of the semiconductor device 104 is improved.

### Embodiment 5

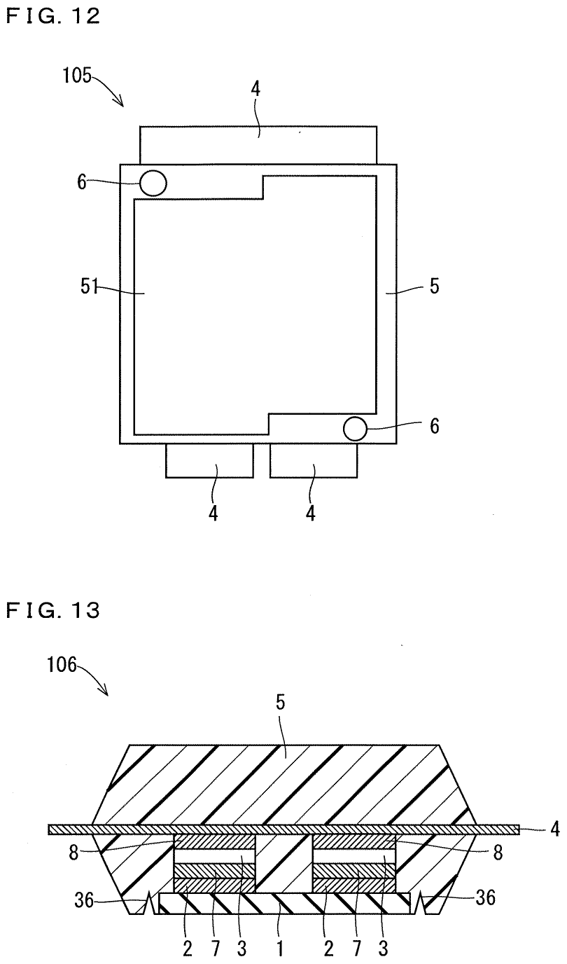

FIG. 12 is a plan view illustrating a configuration of a back surface of a semiconductor device 105 according to Embodiment 5.

The holes 6 provided in the lower surface of the sealing material 5 each have a cylindrical shape as in Embodiment 1. The number of holes 6 is no more than two as in Embodiment 2. An insulating sheet 51 similar to the insulating sheet 1 extends to a portion in which the holes 6 are not provided. Although not illustrated, metal plates similar to the metal plates 2 extend to a portion in which the holes 6 are not provided. That is to say, the insulating sheet 51 and the metal plates according to Embodiment 5 extend to a region other than the holes 6 provided in the lower surface of the sealing material 5 in plan view.

The semiconductor device 105 according to Embodiment 5 is manufactured by the manufacturing method shown in Embodiment 1. The number of sliding protrusions 11 provided in the mold 10 is no more than two as in Embodiment 2. In other words, the sliding protrusions 11 are provided at no more than two locations.

In addition to producing an effect similar to that produced in Embodiment 2, areas of the insulating sheet 51 and the metal plates increase to increase a heat dissipation area. Design tolerance of the semiconductor device 105 is thus improved.

### Embodiment 6

FIG. 13 is a cross-sectional view illustrating a configuration of a semiconductor device 106 according to Embodiment 6.

The holes 36 provided in the lower surface of the sealing material 5 each have a shape gradually decreasing in diameter toward a bottom of the hole 36. In other words, the holes 36 each have a tapered shape. The holes 36 each have a conical shape or a frustoconical shape.

The semiconductor device 106 according to Embodiment 6 is manufactured by the manufacturing method shown in Embodiment 3. That is to say, the sliding protrusions 31 provided in the mold 10 each have a shape gradually decreasing in diameter toward a distal end of the sliding protrusion 31.

When the sealing material 5 is pushed up from the mold 10 with the sliding protrusions 31 in step S6, a surface area of the sliding protrusions 31 to be in contact with the sealing material 5 increases as the holes 36 each have the tapered shape. That is to say, an area of contact between them increases to facilitate release of the sealing material 5 from the mold 10. The frequency of cleaning of the mold 10 and the frequency of re-application of the mold release agent are thus suppressed. The number of times the resin sealing step can be performed per cleaning or per application of the mold release agent increases. As a result, productivity of the semiconductor device 106 is improved.

While the present disclosure has been described in detail, the foregoing description is in all aspects illustrative and not restrictive. It is understood that numerous unillustrated modifications can be devised.

Embodiments of the present disclosure can freely be combined with each other and can be modified or omitted as appropriate.

### EXPLANATION OF REFERENCE SIGNS

1 insulating sheet, 2 metal plate, 3 semiconductor element, 4 lead, 5 sealing material, 6 hole, 7 bonding material, 8 bonding material, 10 mold, 10A top mold, 10B bottom mold, 10C installation surface, 11 sliding protrusion, 12 sliding pin, 31 sliding protrusion, 36 hole, 51 insulating sheet, 101 semiconductor device, 104-106 semiconductor device.

1. A method of manufacturing a semiconductor device, the method comprising:
filling, with a sealing material, an interior of a mold in which an object-to-be-sealed including a semiconductor element is installed and which is opened, the interior of the mold being filled while at least one protrusion projects into the interior of the mold;
sealing the object-to-be-sealed by curing the sealing material; and
releasing the cured sealing material from the mold, wherein
releasing the sealing material includes:
pulling down the projecting protrusion once; and
after pulling down the protrusion once, pushing up the cured sealing material with the protrusion.

2. The method of manufacturing the semiconductor device according to claim 1, the method further comprising
installing, over a portion of an installation surface in the interior of the mold, an insulating sheet to mount thereto the semiconductor element, wherein
in filling the interior of the mold with the sealing material, the protrusion projects into the interior of the mold from a region of the installation surface in the interior of the mold in which the insulating sheet is not installed.

3. The method of manufacturing the semiconductor device according to claim 2, wherein
sealing the object-to-be-sealed includes forming a hole corresponding to the protrusion in the cured sealing material, and
the hole is formed to have an opening in one surface of the sealing material flush with a surface of the insulating sheet exposed from the sealing material and to have a bottom in the sealing material.

4. The method of manufacturing the semiconductor device according to claim 1, wherein
the at least one protrusion is no more than two protrusions.

5. The method of manufacturing the semiconductor device according to claim 1, wherein
the protrusion has a shape gradually decreasing in diameter toward a distal end of the protrusion.

6. A semiconductor device comprising:
an insulating sheet to which an object-to-be-sealed including a semiconductor element is mounted;
a sealing material to seal the object-to-be-sealed; and
at least one hole formed in the sealing material, wherein
the hole is formed to have an opening in one surface of the sealing material flush with a surface of the insulating sheet exposed from the sealing material and to have a bottom in the sealing material.

7. The semiconductor device according to claim 6, wherein
the at least one hole is no more than two holes.

8. The semiconductor device according to claim 7, further comprising
a metal plate provided between the insulating sheet and the semiconductor element, wherein
the insulating sheet and the metal plate extend to a region other than the hole provided in the one surface of the sealing material in plan view.

9. The semiconductor device according to claim 6, wherein
the hole has a shape gradually decreasing in diameter toward a bottom of the hole.
